(19) United States
(12) Patent Application Publication
(10) Pub. No.: US 2025/0225927 A1
(43) Pub. Date: Jul. 10, 2025

(54) DISPLAY PANEL AND DISPLAY DEVICE

(71) Applicant: WUHAN CHINA STAR OPTOELECTRONICS SEMICONDUCTOR DISPLAY TECHNOLOGY CO., LTD., Wuhan, Hubei (CN)

(72) Inventor: Ye JIN, Wuhan, Hubei (CN)

(73) Assignee: WUHAN CHINA STAR OPTOELECTRONICS SEMICONDUCTOR DISPLAY TECHNOLOGY CO., LTD., Wuhan, Hubei (CN)

(21) Appl. No.: 18/561,153

(22) PCT Filed: Sep. 25, 2023
(86) PCT No.: PCT/CN2023/121272

§ 371 Date: Nov. 15, 2023

(30) Foreign Application Priority Data
Aug. 23, 2023 (CN) 202311070048.5

(51) Int. Cl. G09G 3/3225; H10K 59/121; H10K 59/131

(52) U.S. Cl. CPC G09G 3/3225; H10K 59/1213; H10K 59/131; G09G 2300/0426

(57) ABSTRACT

The present application discloses a display panel and a display device. The driver assembly is disposed in a bonding region and includes a first output unit. The multiplex circuit is disposed in a circuit region and includes a first circuit unit. The connection line is connected between the driver assembly and the multiplex circuit and includes a first connection line is connected between the first circuit unit and the first output unit. A plurality of pixel units are disposed in a display region and is connected to the multiplex circuit. The first connection line includes winding line segments distributed in the display region.

### FIELD OF INVENTION

The present application relates to a field of display technologies, especially to a display panel and a display device.

### BACKGROUND OF INVENTION

Organic light emitting diode (OLED) display panels are widely recognized in the industry as having the most development potential, owing to their self-emissive nature, low driving voltage, high luminous efficiency, short response time, high clarity, contrast, and the capability to achieve flexible displays and large-area full-color presentations.

Currently, among the related technologies, a technique that involves laying out fanout lines in the display region (Fanout in Active Area, FIAA) is employed to route fanout wiring from the active area (AA) region to connect it to data lines. This approach helps reduce the footprint of fanout wiring in the lower frame area. However, in situations where there is a higher number of data lines, the increased quantity of fanout wiring required for connecting these data lines results in a need for more space within the AA region. This, in turn, makes it challenging to meet the demands of high-resolution displays.

### SUMMARY OF INVENTION

An embodiment of the present application provides a display panel and a display device that can reduce a wiring space of a first connection line out of a display region to reduce a frame width of the display panel.

The embodiment of the present application provides a display panel, wherein the display panel comprises a display region, a bonding region, and a circuit region located between the display region and the bonding region;
the display panel further comprises:
a driver assembly disposed in the bonding region and comprising a first output unit;
a multiplex circuit disposed in the circuit region and comprising a first circuit unit;
a connection line connected between the driver assembly and the multiplex circuit and comprising a first connection line connected between the first circuit unit and the first output unit; and
a plurality of pixel units disposed in the display region and connected to the multiplex circuit;
wherein the first connection line comprises a winding line segment distributed in the display region.

According to the above objective of the present application, the embodiment of the present application further provides a display device, the display device comprises a display panel, the display panel comprises display region, bonding region and a circuit region located between the display region and the bonding region; the display panel further comprises:
a driver assembly disposed in the bonding region and comprising a first output unit;
a multiplex circuit disposed in the circuit region and comprising a first circuit unit;
a connection line connected between the driver assembly and the multiplex circuit and comprising a first connection line connected between the first circuit unit and the first output unit; and
a plurality of pixel units disposed in the display region and connected to the multiplex circuit;
wherein the first connection line comprises a winding line segment distributed in the display region.

### DESCRIPTION OF DRAWINGS

Specific embodiments of the present invention are described in details with accompanying drawings as follows to make technical solutions and advantages of the present invention clear.

FIG. 1 is a schematic structural view of a partial plane distribution of a display panel provided by an embodiment of the present application;

FIG. 2 is a schematic structural view of another partial plane distribution of the display panel provided by the embodiment of the present application;

FIG. 3 is a schematic circuit structural view of first circuit units and second circuit units provided by the embodiment of the present application;

FIG. 4 is a schematic circuit structural view of the second circuit unit provided by the embodiment of the present application; and

FIG. 5 is a schematic structural view of another partial plane distribution of the display panel provided by the embodiment of the present application; and

FIG. 6 is a schematic structural view of a plane distribution of the display panel provided by the embodiment of the present application.

### DETAILED DESCRIPTION OF PREFERRED EMBODIMENTS

The technical solution in the embodiment of the present application will be clearly and completely described below with reference to the accompanying drawings in the embodiments of the present application. Apparently, the described embodiments are merely some embodiments of the present application instead of all embodiments. According to the embodiments in the present application, all other embodiments obtained by those skilled in the art without making any creative effort shall fall within the protection scope of the present application.

The following disclosure provides many different embodiments or examples to achieve different structures of the present application. To simplify the disclosure of the present application, the components and arrangements of the specific examples are described below. Of course, they are merely examples, and the purpose is not to limit the present application. Furthermore, the present application may repeat reference numerals and/or reference letters in different examples. The repetition is for the purpose of simplification and clarity, and does not by itself indicate the relationship between the various embodiments and/or settings discussed. In addition, the present application provides examples of various specific processes and materials, but a person of ordinary skill in the art can be aware of the application of other processes and/or the use of other materials.

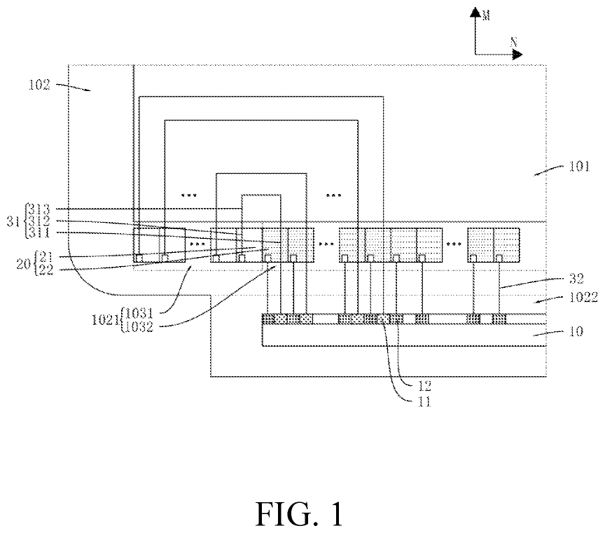

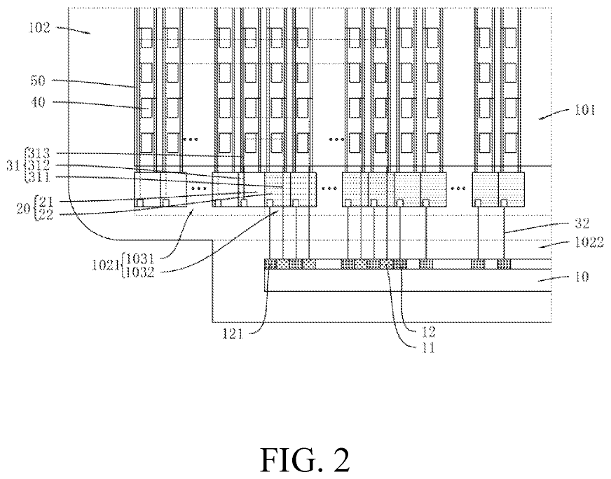

An embodiment of the present application provides a display panel, with reference to FIGS. 1 and 2. The display panel comprises a display region 101, a bonding region 1022 and a circuit region 1021 located between the display region 101 and the bonding region 1022.

Furthermore, the display panel further comprises a driver assembly 10, a multiplex circuit 20, a connection line, and a plurality of pixel units 40. The driver assembly 10 is disposed in the bonding region 1022 and comprises a first output unit 11. The multiplex circuit 20 is disposed in the circuit region 1021 and comprises a first circuit unit 21. The connection line is connected between the driver assembly 10 and the multiplex circuit 20 and comprises a first connection line 31 connected between the first circuit unit 21 and the first output unit 11. The pixel units 40 are disposed in the display region 101 and are connected to a plurality of the multiplex circuits 20.

The first connection line 31 comprises winding line segments 313 distributed in the display region 101.

During embodiment applications, the embodiment of the present application disposes the first connection line 31 between the first circuit unit 21 and the first output unit 11 such that a signal in the driver assembly 10 is transmitted into the display region 101 through the multiplex circuit 20 so a number of the first connection lines 31 relative to data lines of the related art can be reduced. Also, by disposing the winding line segments 313 in the first connection line 31, the first circuit unit 21 can be arranged according to predetermined positions such that winding lines of fanout wirings of the related art can be replaced with the winding line segments 313 of the first connection line 31 between the multiplex circuit 20 and the driver assembly 10 in the embodiment of the present application, which can reduces a number of the winding lines and increase a usable space in the display region 101 to facilitate improvement a resolution of the display panel. Furthermore, the winding line segments 313 in the first connection line 31 are located in the display region 101, which prevents the winding line segments 313 from occupying a space of the circuit region 1021 to further reduce a wiring space of the display region 101 to further reduce a frame width of the display panel and achieve a narrow frame display panel.

In particular, with further reference to FIGS. 1 and 2, the display panel provided by the embodiment of the present application comprises the display region 101 and a non-display region 102 adjacent to the display region 101, and the non-display region 102 can surround the display region 101. Also, the non-display region 102 can comprise the bonding region 1022 located on at least one side of the display region 101 and the circuit region 1021 located between the bonding region 1022 and the display region 101.

Furthermore, the display panel further comprises a plurality of the pixel units 40 disposed in the display region 101, the driver assembly 10 disposed in the bonding region 1022, the multiplex circuit 20 disposed in the circuit region 1021, and a plurality of the connection lines.

A plurality of the pixel units 40 are arranged along a first direction M and a second direction N, and the first direction M is a direction pointing from the bonding region 1022 to the display region 101. The second direction N intersects the first direction M.

In an embodiment, the first direction M is perpendicular to the second direction N.

The pixel units 40 can be divided into a plurality of pixel unit sets arranged along the second direction N, and each of the pixel unit sets comprises a plurality of the pixel units 40 arranged along the first direction M. Namely, each of the pixel unit sets comprises a column of the pixel units 40 arranged along the first direction M.

The driver assembly 10 comprises a plurality of the first output unit 11 and a plurality of second output units 12. In an embodiment, a plurality of the first output unit 11 and a plurality of the second output units 12 can be disposed on a side of the driver assembly 10 near the display region 101.

The multiplex circuit 20 comprises a plurality of the first circuit units 21 and a plurality of second circuit units 22. The connection line comprises a plurality of the first connection lines 31 and a plurality of second connection lines 32. The first output unit 11 is connected to the first circuit unit 21 through the first connection line 31, and the second output units 12 is connected to the second circuit unit 22 through the second connection line 32.

The first connection line 31 comprises a first line segment 311 connected to the first output unit 11 and extending from the bonding region 1022 to the circuit region 1021, a second line segment 312 extending into the circuit region 1021 and connected to the first circuit unit 21, and the winding line segment 313 connected between the first line segment 311 and the second line segment 312 and located in the display region 101. An end of the second connection line 32 is connected to the second output units 12, and another opposite end of the second connection line 32 is connected to the second circuit units 22.

In the embodiment of the present application, one of the pixel unit sets along the first direction M is aligned with one of the first circuit units 21 or is aligned with one of the second circuit units 22, and the display panel further comprises a plurality of data line sets disposed in the display region 101 along the first direction M. One of the data line sets along the first direction M is connected to one of the first circuit units 21 or is connected to one of the second circuit units 22. One of the data line sets is connected to one of the pixel unit sets. Each of the data line sets comprises at least two data lines 50, and the at least two data lines 50 are connected to the pixel units 40 of a corresponding one of the pixel unit sets.

In an embodiment, a number of the data lines 50 of the data line set is four.

It can be understood that by one of the first connection lines 31 connected to one of the first circuit units 21 and one of the first circuit units 21 transmitting a signal to the at least two data lines 50, alternatively, by one of the second connection lines 32 connected to one of the second circuit units 22 and one of the second circuit units 22 transmitting a signal to the at least two data lines 50, a multiplex function of the multiplex circuit 20 is implemented.

A length of the bonding region 1022 along the second direction N is less than a length of the circuit region 1021 along the second direction N such that a part of the driver assembly 10 is misaligned from a part of the multiplex circuit 20. In an embodiment, the circuit region 1021 comprises a second sub-region 1032 aligned with the bonding region 1022 and a first sub-region 1031 connected to the second sub-region 1032 along the second direction N.

In the embodiment of the present application, the first circuit unit 21 is disposed in the first sub-region 1031, and the second circuit units 22 is disposed in the second sub-region 1032 such that the first circuit unit 21 and the second circuit units 22 can be aligned with the corresponding pixel unit sets along the first direction M to prevent setting additional fanout lines corresponding to the data lines in the display region 101 for winding to reduce a wiring space and signal interference.

It should be explained that in the embodiment of the present application, display panel can comprise substrate, a thin film transistor layer disposed on the substrate, a conductive layer disposed on a side of the thin film transistor layer away from substrate, and a light emitting device layer disposed on a side of the conductive layer away from the thin film transistor layer. Furthermore, the light emitting device layer comprises an anode layer disposed on a side of the conductive layer away from the thin film transistor layer, a light emitting layer disposed on a side of the anode layer away from conductive layer, and a cathode layer disposed on a side of the light emitting layer away from the anode layer. The winding line segments 313 of the first connection line 31 can be located in the conductive layer such that the winding line segments 313 can overlap the pixel units 40 respectively without affecting normal light emission of the pixel units 40. Furthermore, the thin film transistor layer comprises display thin film transistors disposed in each of the pixel units 40. The display thin film transistor comprises source and drain electrodes, and the conductive layer can further comprise an adapter portion connected between the source and drain electrodes and the anode layer, the winding line segments 313 and the adapter portions are disposed alternately.

In an embodiment, the first output unit 11 and the first circuit unit 21 are staggered along the first direction M. The second output units 12 are aligned with the second circuit units 22 along the first direction M. One of the first connection lines 31 is connected to one of the first circuit units 21, and one of the second connection lines 32 is connected to one of the second circuit units 22.

With reference to FIGS. 1, 3, and 4, the first circuit unit 21 comprises first multiplex thin film transistors T1 located in the thin film transistor layer, and the first multiplex thin film transistor T1 comprises an active layer, a gate electrode, a source electrode, and a drain electrode. The second circuit unit 22 comprises second multiplex thin film transistors T2 located in the thin film transistor layer, and the second multiplex thin film transistor T2 comprises an active layer, a gate electrode, a source electrode, and a drain electrode.

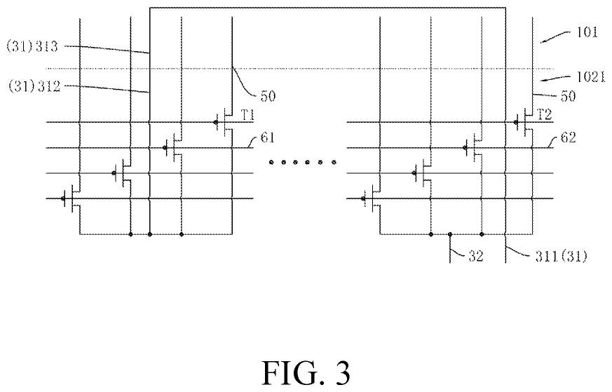

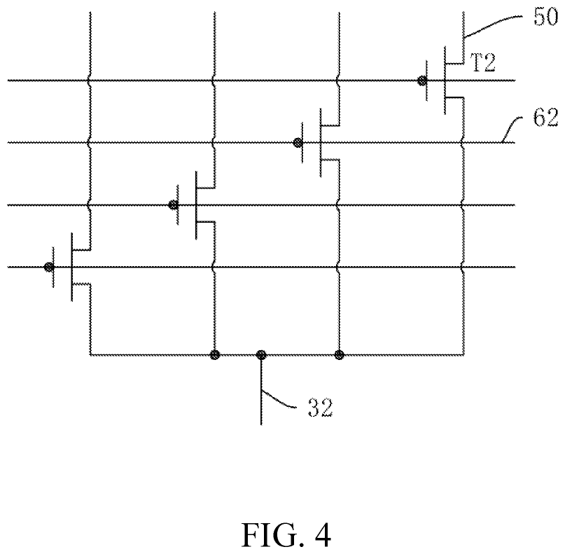

In the multiplex circuit 20, for the first circuit unit 21, one of the first connection lines 31 is connected to source electrodes of the first multiplex thin film transistors T1, one of the data lines 50 is connected to a drain electrode of one of the first multiplex thin film transistors T1, and a first control line 61 is connected to a gate electrode of one of the first multiplex thin film transistors T1. Therefore, in the first circuit unit 21, the first multiplex thin film transistors T1 can be selectively turned on or off by the first control lines 61 such that one of the first connection lines 31 and the first multiplex thin film transistors T1 transmits signals into the data lines 50. Also, FIG. 3 uses one of the first circuit units 21 connected to four of the data lines 50 for instance. Similarly, for the second circuit units 22, one of the second connection lines 32 is connected to source electrodes of the second multiplex thin film transistors T2, one of the data lines 50 is connected to a drain electrode of one of the second multiplex thin film transistors T2. One of the second control lines 62 is connected to a gate electrode of one of the second multiplex thin film transistors T2. Therefore, in the second circuit units 22, the second multiplex thin film transistors T2 can be selectively turned on or off by the second control lines 62 such that one of the second connection lines 32 and the second thin film transistors T2 transmit signals into the data lines 50. Also, FIG. 4 uses one of the second circuit units 22 connected to four of the data lines 50 for instance. It can be understood that with reference to FIGS. 1 and 3, because the first connection line 31 is connected to the first circuit unit 21 sequentially through the first line segment 311, the winding line segments 313, and the second line segment 312, and the second line segment 312 are staggered from the corresponding first circuit unit 21 along the first direction M, the winding line segments 313 are bending in the display region 101 and turned back to be connected to the second line segment 312 such that the second line segment 312 can be aligned with the corresponding first circuit unit 21 along the first direction M. Further, the second line segment 312 extends from a boundary of the display region 101 into the first circuit unit 21 to be connected to the source electrode of the first multiplex thin film transistor T1, and extends with the data lines 50 along the same direction into the first circuit unit 21, as shown in FIG. 3.

It can be understood that FIGS. 3 and 4 are only schematic views of wiring layouts in the first circuit units 21 and the second circuit units 22 provided by the embodiment of the present application, and can be adjusted according to actual demands without limits.

Furthermore, the first output units 11 can be aligned with the second circuit units 22 along the first direction M. It should be explained that both the first line segment 311 and the second line segment 312 are located in the conductive layer such that when the first line segment 311, while extending from the bonding region 1022 into the circuit region 1021, can extend through the second circuit unit 22. Namely, the second line segment 312 can partially overlap the second circuit unit 22, and also, can partially overlap the second multiplex thin film transistor T2.

It should be explained that the embodiment of the present application disposes the first circuit unit 21 and the second circuit units 22 in regions aligned with the pixel unit sets, and then achieves connection between the first circuit units 21 and the first output units 11 and connection between the second circuit units 22 and the second output units 12 by the first connection lines 31 and the second connection lines 32. Because the first output units 11 are staggered from the first circuit units 21 along the first direction M, line segments intersecting the first direction M exist in the first connection lines 31, for example, the winding line segments 313.

As described above, both the first line segment 311 and the second line segment 312 extend along the first direction M. The first line segments 311 are staggered from the second line segment 312 along the first direction M. the winding line segments 313 are bending and distributed in the display region 101. Namely, the embodiment of the present application disposes the first line segment 311 and the second line segment 312 in the first connection line 31 out of the display region 101 as straight line segments, and disposes the bending or folding winding line segments 313 in the display region 101 to effectively reduce a wiring space out of the display region 101 to reduce the frame width. Furthermore, the embodiment of the present application disposes winding lines in the first connection line 31 between the first output unit 11 and the first circuit unit 21 for achieving signal transmission such that the first circuit unit 21 can be aligned with a corresponding one of the pixel unit sets along the first direction M. Therefore, the data lines 50 in the data line sets corresponding to the pixel unit sets can be connected to corresponding ones of the first circuit units 21 along the first direction M. Because the data lines 50 of each of the data line sets are at least two, for instance, four, relative to the related art, the related art requires to dispose fanout wirings corresponding to the data lines 50 for winding, however the embodiment of the present application replaces winding lines of the fanout wiring with the winding line segments 313 in the first connection line 31 between the first circuit unit 21 and the first output unit 11, and a number of the first connection line 31 is less than a number of the data lines 50, namely, it is less than a number of fanout wirings in related art, which prevents a greater number of fanout wirings wound in the display region 101 such that a less number of the first connection lines 31 are wound to further reduce a winding space in the display region 101 and simplify wiring layout difficulty and lower the signal interference.

Furthermore, because the second output units 12 and the second circuit units 22 along the first direction M are aligned, the second connection lines 32 are connected between the second output units 12 and the second circuit units 22 along the first direction M.

Furthermore, the winding line segments 313 in the first connection line 31 do not intersect one another to reduce wiring difficulty.

In an embodiment, the connection lines comprise at least one winding line set, each winding line set comprises a plurality of the winding line segments 313. Also, in one winding line set, the winding line segments 313 are sleeved one by one. the winding line segments 313 in the first connection lines 31 are sleeved one by one. Namely, the winding line segments 313 are sleeved together. The winding line segment 313 in the first connection line 31 connected to the first circuit unit 21 near a side of the second sub-region 1032 is located one an inner side of the sleeved rings, and the winding line segment 313 of the first connection line 31 connected to the first circuit unit 21 away from a side of the second sub-region 1032 is located on an outer side of the sleeved rings. Furthermore, a length of the winding line segment 313 of the first connection line 31 connected to the first circuit unit 21 away from a side of the second sub-region 1032 is greater than a length of the winding line segment 313 of the first connection line 31 connected to the first circuit unit 21 near a side of the second sub-region 1032.

In an embodiment, with reference to FIG. 1, in the driver assembly 10, at least one of the second output units 12 is disposed between two of the first output units 11. For example, one of the second output units 12 is disposed between two of the first output unit 11. Furthermore, the second output units 12 comprise an edge second output unit 121 located at an end portion of the driver assembly 10, the first output unit 11 connected to the first circuit unit 21 away from a side of the second sub-region 1032 is located on a side of the first output unit 11 connected to the first circuit unit 21 near a side of the second sub-region 1032 in which the side of the first output unit 11 is away from a side of the edge second output unit 121. Furthermore, the second output units 12 near edge second output unit 121, one of the first output units 11 is disposed between adjacent two of the second output units 12. In the second output units 12 away from edge second output unit 121, the second output units 12 are disposed adjacently.

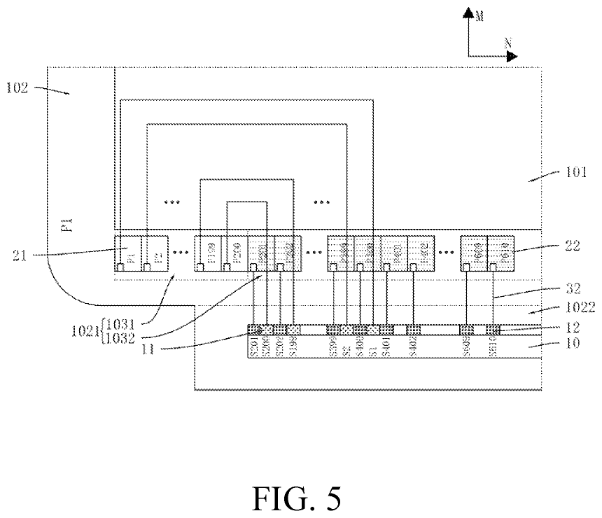

As described above, in an embodiment of the present application, with reference to FIGS. 2 and 5, P1 to P610 are a plurality of circuit units of the multiplex circuit 20, S1 to S610 are a plurality of output units of the driver assembly 10. P1 to P200 are the first circuit units 21, P201 to P610 are the second circuit units 22. S1 to S200 are the first output units 11. S201 to S610 are the second output units 12. In the embodiment of the present application, circuit units of P1 to P610 can be aligned according to corresponding data line sets or pixel unit sets such that the circuit units of P1 to P610 are arranged in turn. Furthermore, edge second output unit 121 at the end portion of the driver assembly 10 is S201, and S201, S202, S199 . . . . S399, S2, S400, S1, S401, S402 . . . S609, S610 are arranged sequentially from a right side of S201. The second output units 12 comprise S201 to S610, and the second output units 12 are arranged sequentially. The first output units 11 comprise S1 to S200, and the first output units 11 are arranged sequentially.

Because P1 connected to S1 is located on a location of the first sub-region 1031 farest away from the second sub-region 1032, a length of the winding line segment 313 corresponding to S1 is greatest such that S1 is located on a location farest away from S20 in S1 to S200 1. Because P200 connected to S200 is located on a location of the first sub-region 1031 nearest the second sub-region 1032, a length of the winding line segment 313 corresponding to S2 is minimal such that S200 is adjacent to S201. Similarly, remains of the first output units 11 are arranged according to locations of the first circuit unit 21 connected to the first output units 11 such that S1 to S200 are arranged from left to right in a reverse order. Also, the edge second output unit 121 (S210) is on the end portion of the driver assembly 10, S200 is located between S201 and S202. S199 is located between S202 and S203 (not shown in the figures). S2 is located between S399 and S400. S1 is located between S400 and S401. As described above, the driver assembly 10 of the embodiment of the present application, in, the first output unit 11 are arranged in a reverse order, the second output units 12 are arranged sequentially, and the first output unit 11 and the second output units 12 are arranged alternately in an random order, also, the winding line segments 313 sleeved in the first connection line 31 such that the circuit units P1 to P610 can be arranged sequentially. Namely, the circuit units can be aligned with corresponding data line sets or pixel unit sets.

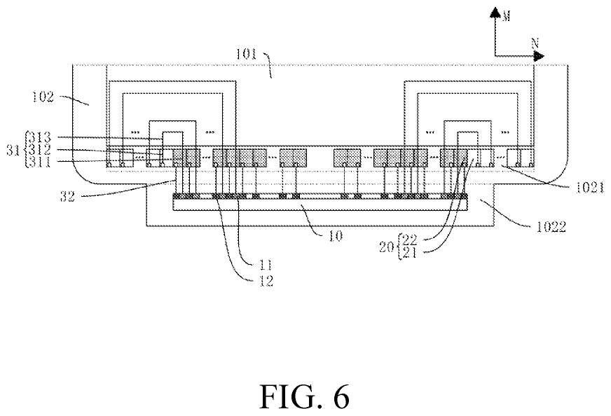

Furthermore, with reference to FIG. 6, the first connection lines 31, the second connection lines 32, the driver assembly 10, and the multiplex circuit 20 on a left side and a right side of FIG. 6 are symmetrically arranged. It can be understood that the winding line segments 313 on the left side of FIG. 6 constitute a winding line set, the winding line segments 313 on the right side of FIG. 6 constitute a winding line set. Similarly, connection between the multiplex circuit 20 and the pixel unit sets and the data line sets are the same, which will not be described repeatedly here.

As described above, the embodiment of the present application sets the first line segment 311 and the second line segment 312 in the first connection line 31 located out of the display region 101 as straight line segments, and sets the bending or folding winding line segments 313 in the display region 101 to effectively reduce a wiring space out of the display region 101 to reduce the frame width. Furthermore, the embodiment of the present application disposes winding lines in the first connection line 31 between the first output unit 11 and the first circuit unit 21 for achieving signal transmission such that the first circuit unit 21 can be aligned with a corresponding one of the pixel unit sets along the first direction M. Therefore, the data lines 50 in the data line sets corresponding to the pixel unit sets can be connected to corresponding ones of the first circuit units 21 along the first direction M. Because the data lines 50 of each of the data line sets are at least two, for instance, four, the embodiment of the present application prevents a greater number of the data lines 50 are wound in the display region 101 such that a less number of the first connection lines 31 are wound to reduce a wiring space of the winding lines in the display region 101, simplifies wiring difficulty, and lowers signal interference.

Furthermore, the embodiment of the present application further comprises a display device, the display device comprises the display panel in the above embodiment.

The display device disposes the display panel provided by the above embodiment of the present application, the display device has the same advantages of the above display panel.

In an embodiment, the display device can comprise television, computer, cell phone, tablet and other display apparatus.

In the above-mentioned embodiments, the descriptions of the various embodiments are focused. For the details of the embodiments not described, reference may be made to the related descriptions of the other embodiments.

The display panel and the display device provided by the embodiment of the present application are described in detail as above. The principles and implementations of the present application are described in the following by using specific examples. The description of the above embodiments is only for assisting understanding of the technical solutions of the present application and the core ideas thereof. Those of ordinary skill in the art should understand that they can still modify the technical solutions described in the foregoing embodiments or equivalently replace some of the technical features. These modifications or replacements do not make the essence of the technical solutions depart from a range of the technical solutions of the embodiments of the present application.

What is claimed is:

1. A display panel, wherein the display panel comprises a display region, a bonding region, and a circuit region located between the display region and the bonding region;
the display panel further comprises:
a driver assembly disposed in the bonding region and comprising a first output unit;
a multiplex circuit disposed in the circuit region and comprising a first circuit unit;
a connection line connected between the driver assembly and the multiplex circuit and comprising a first connection line connected between the first circuit unit and the first output unit; and
a plurality of pixel units disposed in the display region and connected to the multiplex circuit;
wherein the first connection line comprises a winding line segment distributed in the display region.

2. The display panel according to claim 1, wherein the first connection line further comprises a first line segment extending from the bonding region to the circuit region and connected to the first output unit, and a second line segment extending from a boundary of the display region to the circuit region and connected to the first circuit unit, and the winding line segment is connected between the first line segment and the second line segment.

3. The display panel according to claim 2, wherein the first line segment and the second line segment extend from a first direction, and the first direction is a direction pointing from the bonding region to the display region, the first line segment and the second line segment are staggered along the first direction, the winding line segment is distributed in a bending shape in the display region.

4. The display panel according to claim 2, wherein the first output unit and the first circuit unit are staggered along the first direction.

5. The display panel according to claim 2, wherein the multiplex circuit comprises a plurality of second circuit units, the first circuit units and the second circuit units are arranged along a second direction, the second direction intersects the first direction, the driver assembly comprises a plurality of second output units, the first output units and the second output units are arranged along the second direction, the connection line further comprises a plurality of second connection lines;
wherein the second connection lines extend along the first direction and are connected between the second circuit units and the second output units.

6. The display panel according to claim 5, wherein the connection line comprises the first connection lines, and the winding line segments of the first connection line are not intersected.

7. The display panel according to claim 6, wherein the connection line comprises at least one winding line set, each of the least one winding line set comprises a plurality of the winding line segments, and in each of the least one winding line set, the winding line segments are sleeved one by one.

8. The display panel according to claim 5, wherein a length of the bonding region along the second direction is less than the circuit region along a length of the second direction, and the circuit region comprises a first sub-region and a second sub-region, the second sub-region and the bonding region are aligned with each other along the first direction, and the first sub-region is connected to the second sub-region along the second direction;
wherein the first circuit units are distributed in the first sub-region, and the second circuit units are distributed in the second sub-region.

9. The display panel according to claim 8, wherein the second output units comprise an edge second output unit located at an end portion of the driver assembly, the first output unit connected to the first circuit unit away from a side of the second sub-region is located on a side of the first output unit connected to the first circuit unit near a side of the second sub-region in which the side of the first output unit is away from a side of the edge second output unit.

10. The display panel according to claim 9, wherein in the driver assembly, in the second output units near the edge second output unit, one of the first output units is located between adjacent two of the second output units, and in the second output units away from the edge second output unit, the second output units are disposed adjacently.

11. The display panel according to claim 8, wherein a length of the winding line segment of the first connection line connected to the first circuit unit away from a side of the second sub-region is greater than a length of the winding line segment of the first connection line connected to the first circuit unit near a side of the second sub-region.

12. The display panel according to claim 5, wherein the second circuit units are aligned with the second output units along the first direction.

13. The display panel according to claim 5, wherein a plurality of the pixel unit comprises a plurality of pixel unit sets arranged along the second direction, and each of the pixel unit sets comprises a plurality of the pixel units arranged along the first direction;
wherein one of the pixel unit sets along the first direction is aligned with one of the first circuit units or one of the second circuit units.

14. The display panel according to claim 13, wherein the display panel further comprises a plurality of data line sets, one of the data line sets is connected to one of the pixel unit sets, each of the data line sets comprises at least two data lines extending along the first direction, and the data lines are connected to the pixel units of a corresponding one of the pixel unit sets;
wherein one of the data line sets along the first direction is connected to a corresponding one of the first circuit units or a corresponding one of the second circuit units.

15. The display panel according to claim 14, wherein the display panel comprises a substrate, and a thin film transistor layer disposed on the substrate, the first circuit unit comprises a plurality of first multiplex thin film transistors located in the thin film transistor layer, and the second circuit unit comprises a plurality of second multiplex thin film transistors located in the thin film transistor layer;
wherein one of the first connection lines is connected to source electrodes of a plurality of the first multiplex thin film transistors, one of the data lines is connected to a drain electrode of one of the first multiplex thin film transistors, one of the second connection lines is connected to source electrodes of a plurality of the second multiplex thin film transistors, one of the data lines is connected to a drain electrode of one of the second multiplex thin film transistors.

16. The display panel according to claim 15, wherein the display panel further comprises a conductive layer disposed on a side of the thin film transistor layer away from the substrate and a light emitting device layer disposed on a side of the conductive layer away from the thin film transistor layer;
wherein the conductive layer comprises the first line segment, the second line segment, and the winding line segment.

17. The display panel according to claim 15, wherein the first line segment partially overlaps the second circuit unit, the second line segment extends from a boundary of the display region to the first circuit unit and is connected to source electrodes of the first multiplex thin film transistors.

18. A display device, comprising a display panel, wherein the display panel comprises display region, bonding region and a circuit region located between the display region and the bonding region;
the display panel further comprises:
a driver assembly disposed in the bonding region and comprising a first output unit;
a multiplex circuit disposed in the circuit region and comprising a first circuit unit;
a connection line connected between the driver assembly and the multiplex circuit and comprising a first connection line connected between the first circuit unit and the first output unit; and
a plurality of pixel units disposed in the display region and connected to the multiplex circuit;
wherein the first connection line comprises a winding line segment distributed in the display region.

19. The display device according to claim 18, wherein the first connection line further comprises a first line segment extending from the bonding region to the circuit region and connected to the first output unit, and a second line segment extending from a boundary of the display region to the circuit region and connected to the first circuit unit, and the winding line segment is connected between the first line segment and the second line segment.

20. The display device according to claim 19, wherein the first line segment and the second line segment extend from a first direction, and the first direction is a direction pointing from the bonding region to the display region, the first line segment and the second line segment are staggered along the first direction, the winding line segment is distributed in a bending shape in the display region.
